(19) United States
(12) Patent Application Publication
(10) Pub. No.: US 2025/0239291 A1
(43) Pub. Date: Jul. 24, 2025

(54) INDICATION FOR EXITING REFRESH OF AN INVALID MEMORY BLOCK

(71) Applicant: Micron Technology, Inc., Boise, ID (US)

(72) Inventor: Jianxiong Huang, Shanghai (CN)

(21) Appl. No.: 19/022,900

(22) Filed: Jan. 15, 2025

Related U.S. Application Data
(60) Provisional application No. 63/623,123, filed on Jan. 19, 2024.

(51) Int. Cl. G11C 11/406; G11C 11/4096

(52) U.S. Cl. CPC G11C 11/40618; G11C 11/40615; G11C 11/4096

(57) ABSTRACT

Methods, systems, and devices for indication for exiting refresh of an invalid memory block are described. A memory system may store a refresh flag that indicates, during execution of a refresh operation, whether a source memory block of the refresh operation is valid. The refresh operation may be performed in portions, and the memory system may check the refresh flag during the refresh operation to determine whether to continue performing remaining portions of the refresh operation. If a controller of the memory system, or a host system, identifies that a memory block is invalid, the controller of the memory system or the host system may clear the refresh flag for the memory block. If the memory system identifies that the refresh flag is cleared during the refresh operation, the memory system may abort the refresh operation and may refrain from performing remaining portion(s) of the refresh operation.

### CROSS REFERENCE

The present application for patent claims priority to U.S. Patent Application No. 63/623,123 by Huang, entitled “INDICATION FOR EXITING REFRESH OF AN INVALID MEMORY BLOCK,” filed Jan. 19, 2024, which is assigned to the assignee hereof, and which is expressly incorporated by reference in its entirety herein.

### TECHNICAL FIELD

The following relates to one or more systems for memory, including an indication for exiting refresh of an invalid memory block.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports an indication for exiting refresh of an invalid memory block in accordance with examples as disclosed herein.

FIG. 2 shows an example of a system that supports an indication for exiting refresh of an invalid memory block in accordance with examples as disclosed herein.

FIG. 3 shows an example of a flow diagram that supports an indication for exiting refresh of an invalid memory block in accordance with examples as disclosed herein.

FIG. 4 shows an example of a flow diagram that supports an indication for exiting refresh of an invalid memory block in accordance with examples as disclosed herein.

FIG. 5 shows a block diagram of a memory system that supports an indication for exiting refresh of an invalid memory block in accordance with examples as disclosed herein.

FIG. 6 shows a flowchart illustrating a method or methods that support an indication for exiting refresh of an invalid memory block in accordance with examples as disclosed herein.

### DETAILED DESCRIPTION

A memory system may periodically refresh data stored in the memory system. The memory system may schedule memory blocks in the memory system to be refreshed. During a refresh of a memory block, the memory block, which may be referred to herein as a source memory block, may be removed from a set of available blocks in the memory system (e.g., removed from a data list) until the refresh is complete. That is, the source memory block may not be available for one or more other access operations during the refresh. In some examples, data in the memory block being refreshed may become invalid during the refresh, for example, due to a host system overwriting the data or the data being garbage collected, among other examples. However, because the memory block may be undergoing a refresh operation, the memory system may be unable to reuse the memory block for other access operations until after the refresh operation has completed. Thus, if the memory block becomes invalid during a refresh operation, the memory block may occupy excess memory storage until at least after the refresh operation is complete and even beyond.

To improve memory storage efficiency, techniques described herein provide for the memory system to utilize (e.g., and store) a refresh flag (e.g., a refresh indication) that indicates, during execution of a refresh operation, whether the source memory block of the refresh operation is valid. The memory system may perform the refresh operation in portions, and the memory system may check the refresh flag based on (e.g., after, concurrent with) each portion of the refresh operation (e.g., periodically or after a quantity of memory units are refreshed) to determine whether to continue performing the refresh operation. The memory system may set the refresh flag for a corresponding memory block to a first value based on or in response to the memory block being scheduled for a refresh operation. If a controller of the memory system, or a host system, or some other entity, identifies that a memory block has become invalid, the controller or the host system may set (e.g., clear, reset) the refresh flag for the identified memory block. During the refresh operation (or before initiating the refresh operation), the memory system may check the refresh flag. If the memory system identifies that the refresh flag is for example cleared, the memory system may exit (e.g., end, terminate, abort) the refresh operation. Exiting the refresh operation may enable the source memory block to be released (e.g., garbage collected) and reused for other access operations, thereby increasing an amount of memory available to the memory system and increasing efficiency of memory operations as compared with systems in which the memory block is not reused until after the refresh operation is complete, among other advantages.

In addition to applicability in memory systems as described herein, techniques for indication for exiting refresh of an invalid memory block may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling more efficient memory storage, which may decrease processing or latency times, improve response times, or otherwise improve user experience, among other benefits.

In addition to applicability in memory systems described herein, techniques for indication for exiting refresh of an invalid memory block may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by enabling efficient memory storage and increasing memory capacity, and may incur lower latency costs (e.g., by implementing it at hardware level) or use less power relative to other solutions, among other benefits.

Features of the disclosure are illustrated and described in the context of systems, devices, and circuits. Features of the disclosure are further illustrated and described in the context of block diagrams and flowcharts.

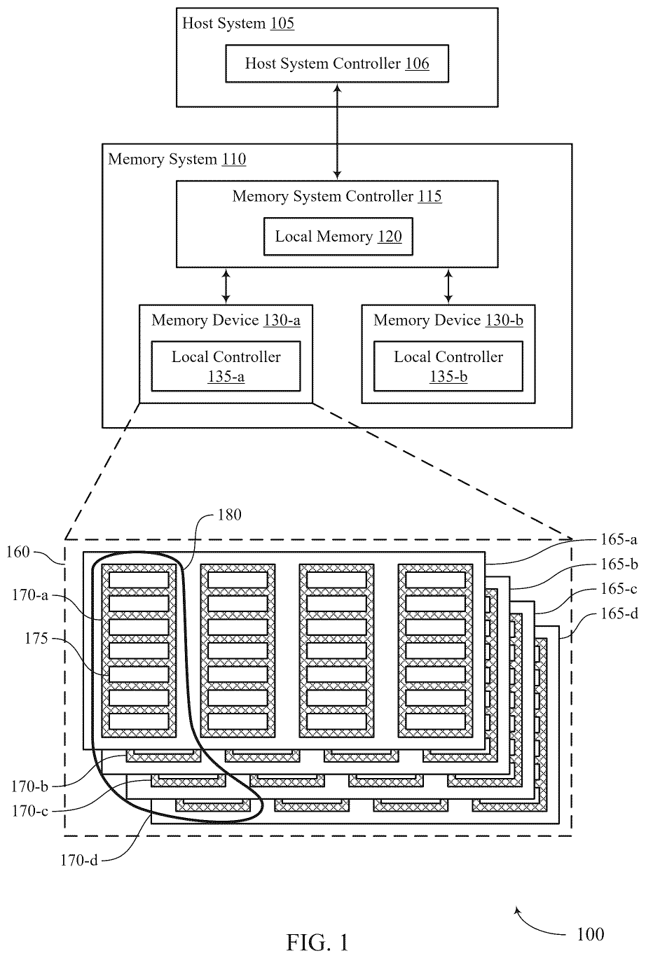

FIG. 1 shows an example of a system 100 that supports indication for exiting refresh of an invalid memory block in accordance with examples as disclosed herein. The system 100 includes a host system 105 coupled with a memory system 110. The system 100 may be included in a computing device such as a desktop computer, a laptop computer, a network server, a mobile device, a vehicle (e.g., automobile, train, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

The system 100 may include any quantity of non-transitory computer readable media that support indication for exiting refresh of an invalid memory block. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

A memory system 110 may periodically refresh data stored in one or more memory devices 130. The memory system 110 may schedule a virtual block 180 in a memory device 130-a to be refreshed. During a refresh of the virtual block 180, the virtual block 180, which may be referred to herein as a source virtual block, may be removed from a set of available virtual blocks 180 in the memory system 110 (e.g., removed from a data list). In some examples, data in the virtual block 180 being refreshed may become invalid, for example, due to a host system 105 overwriting the data, or the data being garbage collected, among other examples. However, because the virtual block 180 may be undergoing a refresh operation, the memory system 110 may be unable to erase and reuse the virtual block 180 for other access operations until after the refresh operation has completed, and the virtual block 180 may occupy excess memory storage in the memory device 130-a.

To improve memory storage efficiency as described herein, the memory system 110 may utilize (e.g., and store in a memory device 130) a refresh flag (e.g., a refresh indication) that indicates, during execution of a refresh operation, whether the source virtual block 180 of the refresh operation is valid. The refresh operation may be performed in portions, and the memory system 110 may check the refresh flag during the refresh operation (e.g., periodically or after a quantity of memory units are refreshed) to determine whether to continue performing the refresh operation. The refresh flag may be set to a first value in response to a refresh operation being scheduled for a corresponding virtual block 180. If the memory system controller 115, or a host system 105 (e.g., a host system controller 106), identifies that a virtual block 180 is invalid, the memory system controller 115 or the host system 105 may clear the refresh flag for the virtual block 180. During the refresh operation (or before initiating the refresh operation), the memory system 110 may check the refresh flag and determine that the refresh flag is cleared, and the memory system 110 may abort the refresh operation. Aborting the refresh operation may enable the source virtual block 180 to be released (e.g., garbage collected) and reused for other access operations, thereby increasing an amount of memory available to the memory system 110 and increasing efficiency of memory operations for the memory system 110.

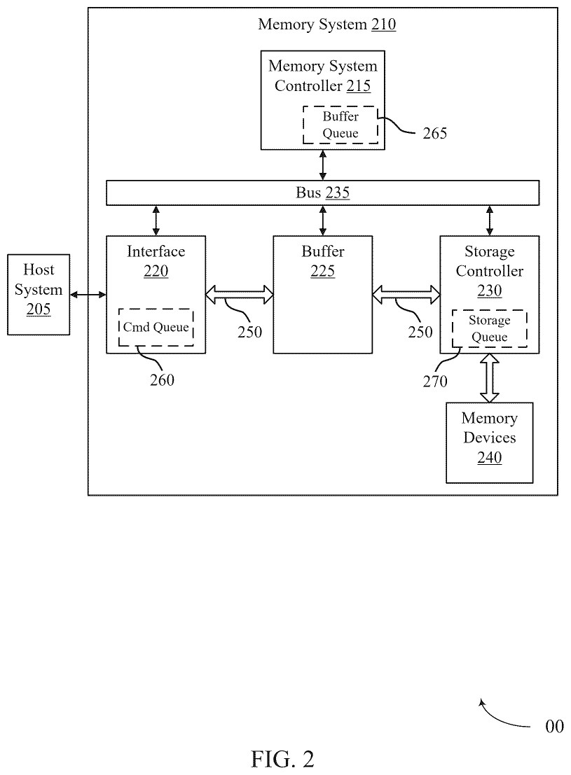

FIG. 2 shows an example of a system 200 that supports indication for exiting refresh of an invalid memory block in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240 directly or via a bus (not shown), which may include using a protocol specific to each type of memory device 240. In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received in response to the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) that the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

After the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

A memory system 210 may periodically refresh data stored in one or more memory devices 240. The memory system 210 may schedule a memory block (e.g., a virtual block 180) in a memory device 240 to be refreshed. During a refresh of the memory block, the memory block, which may be referred to herein as a source virtual block, may be removed from a set of available memory blocks in the memory system 210 (e.g., removed from a data list). In some examples, data in the memory block being refreshed may become invalid, for example due to a host system 205 overwriting the data or the data being garbage collected. However, because the memory block may be undergoing a refresh operation, the memory system 210 may be unable to reuse the memory block for other access operations until after the refresh operation has completed, and the memory block may occupy excess memory storage in the memory devices 240.

In accordance with examples described herein, a memory system 210 and/or a host system 205 may store, maintain, and update a refresh flag (e.g., refresh indication) for memory blocks stored in memory devices 240 to monitor (e.g., track) whether the memory blocks are scheduled for refresh, and, of the memory blocks that are scheduled for refresh, whether the memory blocks contain valid data. The memory system controller 215 (e.g., or the storage controller 230) may store one or more refresh flags in the memory devices 240. Additionally, or alternatively, the refresh flag may be coupled with the memory system controller 215 or the host system 205, or both. In some examples, the memory devices 240 may store multiple refresh flags, one for each memory block of the memory devices 240. Additionally, or alternatively, the one or more refresh flags may be stored in memory in the host system 205, and the host system may indicate a value of the one or more refresh flags to the memory system 210 (e.g., via the interface 220), for example, periodically or in response to a request. If the host system overwrites data in a memory block (e.g., thereby invalidating the data), the memory system controller 215 (e.g., or the storage controller 230) may clear the refresh flag associated with the overwritten memory block. In some examples, the memory system controller 215, or the storage controller 230, may garbage collect a memory block, and the memory system controller (e.g., or the storage controller 230) may clear the refresh flag associated with the garbage collected memory block. During, or before, execution of a refresh operation, the memory system controller 215 may fetch a value of the refresh flag from the memory devices 240 (e.g., internal to the memory system 210) or from the host system 205 (e.g., external to the memory system 210), and the value of the refresh flag may indicate whether to continue (e.g., perform) the refresh operation or exit (e.g., abort) the refresh operation.

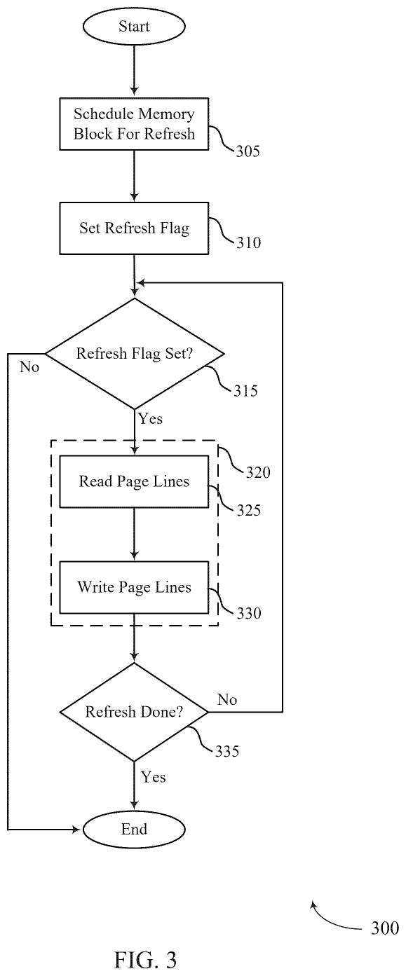

FIG. 3 shows an example of a flow diagram 300 that supports indication for exiting refresh of an invalid memory block in accordance with examples as disclosed herein. The flow diagram 300 may implement or may be implemented by aspects of the system 100 or the system 200. For example, the flow diagram 300 may be implemented by a memory system 110 (e.g., or a memory system 210), and one or more steps performed by the memory system 110 in the flow diagram 300 may be implemented in instructions or firmware stored on memory of the memory system 110 (e.g., a memory device 130) and may be executed by a memory system controller 115 (and/or a local controller 135).

Aspects of the flow diagram 300 may be implemented by one or more controllers, such as an interface controller, among other components. Additionally or alternatively, aspects of the flow diagram 300 may be implemented as instructions stored in one or more memories (e.g., firmware stored in the volatile memory 120 and/or the non-volatile memory 125). For example, the instructions, when executed by one or more controllers (e.g., the interface controller 115), may cause the one or more controllers (or a device or a system) to perform the operations of the flow diagram 300. It is to be understood that various aspects of the flow diagram 300 may be performed by one or more various components of the memory system, including one or more memory system controllers, one or more memory device controllers, firmware, hardware, or any combination thereof.

In the following description of the flow diagram 300, the operations may be performed in a different order than the order shown, or other operations may be added or removed from the flow diagram 300. For example, some operations may also be left out of the flow diagram 300, may be performed in different orders or at different times, or other operations may be added to the flow diagram 300.

At 305, a memory block may be scheduled for a refresh operation. For example, a memory system (e.g., a memory system controller 115) may schedule the memory block for refresh. The memory block scheduled for the refresh may be referred to as a source memory block (e.g., a source virtual block) or a refresh source memory block. In some examples, the memory block may be a virtual block (e.g., a virtual block 180). In some other examples, the memory block may be a group of virtual blocks, an individual block (e.g., a block 170), or any other unit of memory (e.g., a page 175, a plane 165, a string).

At 310, a refresh flag may be set. For example, the memory system (e.g., the memory system controller 115) may set the refresh flag (e.g., a refresh indication) to a first value in direct response to, or after, the memory block being scheduled for the refresh operation. The first value may indicate that the memory block is valid and is currently being refreshed. For example, the first value may indicate that the memory block includes valid data, that a valid page count of the memory block is non-zero, or both. The refresh flag may be stored in memory of the memory system (e.g., a memory device 130) and may include a single bit or a set of bits. The refresh flag may represent an example of a mode register, a pin, or some other set of data or indication of validity. In some examples, the memory system may maintain a respective refresh flag for each memory block, or the memory system may maintain one refresh flag for multiple memory blocks, or some other ratio of refresh flags to memory blocks.

At 315, the refresh flag may be monitored and it may be determined whether the refresh flag is set to the first value or not. For example, the memory system (e.g., the memory system controller 115) may monitor a value of the refresh flag during execution of a refresh operation. The memory system may, in some examples, perform the refresh operation in iterations 320, and the memory system may monitor the refresh flag between iterations 320 of the refresh operation. In some examples, an iteration 320 may include reading a quantity of page lines and refresh writing a quantity of page lines. A value of the refresh flag may indicate whether the memory block is valid for the refresh operation, and the memory system may determine whether to continue to perform the refresh operation in response to (e.g., based on) the value of the refresh flag.

The memory system (e.g., the memory system controller 115) may monitor the value of the refresh flag before initiating the refresh operation (e.g., before a first iteration 320), before performing each of one or more iterations (e.g., additional iterations) of the refresh operation, or any combination thereof. For example, the memory system may perform one or more iterations 320 of the refresh operation and may, at 315, check the value of the refresh indication after each iteration 320. In some examples, the memory system may check the flag periodically, for example after a threshold time has elapsed or at a preconfigured periodicity. In some other examples, the memory system may check the flag in response to (e.g., in direct response to) a threshold quantity of memory units (e.g., a quantity of page lines, a quantity of memory cells) being refreshed.

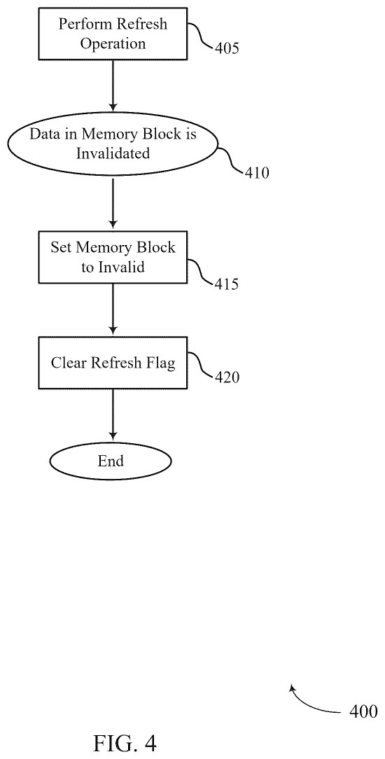

In some examples, a host system (e.g., a host system 105) may set the refresh flag to a second value (e.g., clear the refresh flag), as described in greater detail elsewhere herein, including with reference to FIG. 4. The host system may clear the refresh flag before the memory system performs, or initiates, the refresh operation (e.g., before a first iteration 320 of the refresh operation), or during the refresh operation (e.g., between successive iterations 320 of the refresh operation, or during an iteration 320).

If, at 315, the memory system determines that the refresh flag is clear (e.g., not set, set to a second value, set to 0, indicating that the memory block is invalid), the memory system may exit (e.g., abort) the refresh operation, which may end the flow diagram 300. In response to exiting the refresh operation, the memory system may release the source virtual block associated with the refresh operation. For example, the memory system may perform garbage collection on the source virtual block, or may schedule the source virtual block for one or more access operations different than the refresh operation, in response to the refresh flag being cleared and the memory system exiting the refresh operation.

If, at 315, the memory system determines that the refresh flag is set (e.g., set to a first value, set to 1), the memory system may perform an iteration 320 (e.g., a portion of) the refresh operation. At 325, as part of performing an iteration 320 of one or more iterations of the refresh operation, one or more page lines of the memory block may be read. For example, the memory system (e.g., the memory system controller 115) may read the respective set of page lines from the memory block for refresh. The set of page lines may include a quantity of page lines (e.g., one page line, three page lines, or some other quantity of page lines). At 330, in direct response to reading the set of page lines and as part of performing the iteration 320, refreshed data may be written to the respective set of page lines. For example, the memory system may write the refreshed data to the respective set of page lines in the memory block. By reading the respective page lines and writing refreshed data to the respective set of page lines, the refresh operation may refresh data in the source virtual block associated with the refresh operation. In some examples, a quantity of page lines that are refreshed in each iteration 320 may be selected according to a periodicity associated with the refresh operation, a total amount of data in the memory block, a granularity of memory storage, one or more other parameters, or any combination thereof.

At 335, it may be determined whether the refresh operation is complete. For example, the memory system (e.g., the memory system controller 115) may determine whether the refresh operation is complete in response to completing an iteration 320. If the memory system determines that the refresh operation is complete, the memory system may refrain from performing any additional iterations 320 of the refresh operation, which may end the flow diagram 300. If the memory system determines that the refresh operation is not complete, the memory system may monitor the refresh flag at 315 before performing additional iterations 320 of the refresh operation.

The memory system may complete the refresh operation (e.g., determine that the refresh operation is complete) in response to refreshing each page of a set of pages of the memory block (e.g., the source virtual block) and/or in response to the refresh flag being set to the first value. The memory system may thereby utilize the refresh flag to determine whether to continue a refresh operation for a memory block or whether to abort the refresh operation. The refresh flag may provide for the memory system to refrain from continuing refresh for an invalid memory block, which may provide for improved memory storage and efficiency, among other examples, as compared with systems in which a memory system does not check a refresh flag during the refresh operation.

FIG. 4 shows an example of a flow diagram 400 that supports indication for exiting refresh of an invalid memory block in accordance with examples as disclosed herein. The flow diagram 400 may implement or may be implemented by aspects of the system 100 or the system 200. For example, the flow diagram 400 may be implemented by a memory system 110 (e.g., or a memory system 210), and one or more steps performed by the memory system 110 in the flow diagram 400 may be implemented in instructions or firmware stored on memory of the memory system 110 (e.g., a memory device 130) and may be executed by a memory system controller 115 (and/or a local controller 135).

Aspects of the flow diagram 400 may be implemented by one or more controllers, such as an interface controller, among other components. Additionally or alternatively, aspects of the flow diagram 400 may be implemented as instructions stored in one or more memories (e.g., firmware stored in the volatile memory 120 and/or the non-volatile memory 125). For example, the instructions, when executed by one or more controllers (e.g., the interface controller 115), may cause the one or more controllers (or a device or a system) to perform the operations of the flow diagram 400. It is to be understood that various aspects of the flow diagram 400 may be performed by one or more various components of the memory system, including one or more memory system controllers, one or more memory device controllers, firmware, hardware, or any combination thereof.

In the following description of flow diagram 400, the operations may be performed in a different order than the order shown, or other operations may be added or removed from the flow diagram 400. For example, some operations may also be left out of flow diagram 400, may be performed in different orders or at different times, or other operations may be added to flow diagram 400.

At 405, a refresh operation may be performed on a memory block (e.g., a refresh source memory block). The refresh operation may be partially or fully performed. For example, the memory system (e.g., the memory system controller 115) may initiate the refresh operation for the memory block (e.g., based on setting a refresh indication to a first value) and may perform a portion (e.g., an iteration 320) of the refresh operation. The memory system and/or host system may set a refresh flag to a first value in response to initiating the refresh operation. As part of the refresh operation, the memory system may check a refresh flag (e.g., periodically, in response to refreshing a threshold quantity of page lines) before performing each iteration of one or more iterations of the refresh operation, as described in greater detail with reference to FIG. 3.

At 410, data in a memory block (e.g., a source virtual block associated with a refresh operation) may become invalidated. For example, a host system (e.g., a host system controller 106) may overwrite data in the source memory block. That is, the host system (e.g., a host device) may write second data to the memory block, and the second data may overwrite the data stored in the memory block. The host system may overwrite the data, thereby invalidating the data in the source memory block, during execution of a refresh operation on the source memory block. In some examples, the host system (e.g., a host device) or the memory system (e.g., the memory system controller 115) may perform garbage collection on the source memory block. As part of garbage collection, the host system or the memory system controller may move data from the source memory block to a destination memory block (e.g., a garbage collection destination virtual block). The host system or the memory system may perform the garbage collection that invalidates the data in the source memory block during execution of a refresh operation on the source memory block. An invalid memory block may include all invalid data, or the invalid memory block may include some invalid data and some valid data.

At 415, the source memory block may be set to invalid. For example, the memory system (e.g., the memory system controller 115) may label the memory block as invalid or may move the source memory block to a group of memory blocks that are invalid. The memory system may schedule invalid memory blocks for access operations (e.g., may reuse invalid memory blocks) in response to determining that the memory blocks are invalid. In some examples, the source memory block may be set to invalid in response to a valid page count for the source memory block satisfying a threshold (e.g., equaling zero). The valid page count may be associated with, or may indicate, a quantity of pages of the memory block that include invalid data. That is, the source memory block being set to invalid may indicate that the memory block does not have any valid pages of data or that the valid page count associated with the source memory block is zero.

At 420, the refresh flag may be cleared. For example, the memory system (e.g., the memory system controller 115) or the host system (e.g., a host system controller 106) may set the refresh flag (e.g., refresh indication) to a second value that indicates the source memory block is invalid. The refresh flag may be cleared in response to the host system overwriting the data stored in the source memory block or in response to the memory system or the host system moving data from the source memory block to a garbage collection destination memory block. In response to the refresh flag being cleared, the memory system may exit (e.g., abort) the refresh operation and/or release the source memory block, as described in greater detail with reference to FIG. 3.

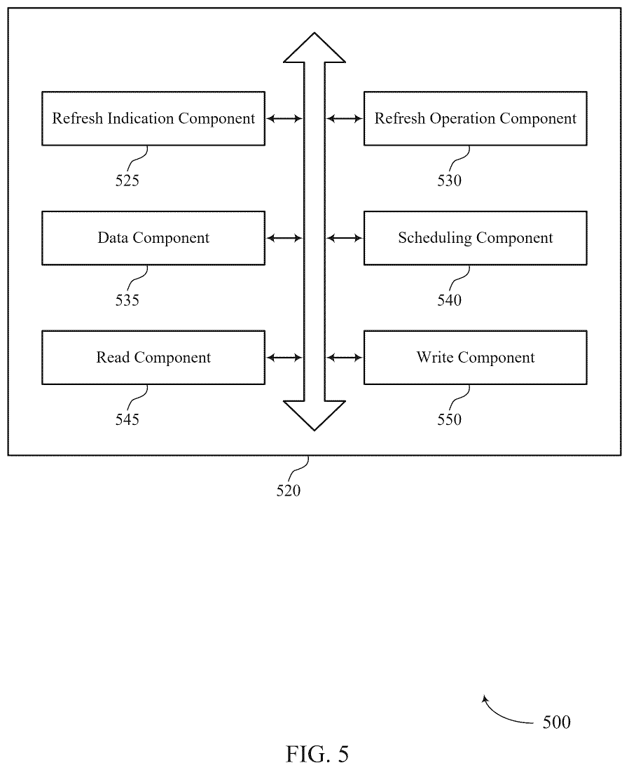

FIG. 5 shows a block diagram 500 of a memory system 520 that supports indication for exiting refresh of an invalid memory block in accordance with examples as disclosed herein. The memory system 520 may be an example of aspects of a memory system as described with reference to FIGS. 1 through 4. The memory system 520, or various components thereof, may be an example of means for performing various aspects of indication for exiting refresh of an invalid memory block as described herein. For example, the memory system 520 may include a refresh indication component 525, a refresh operation component 530, a data component 535, a scheduling component 540, a read component 545, a write component 550, or any combination thereof. Each of these components, or components of subcomponents thereof (e.g., one or more processors, one or more memories), may communicate, directly or indirectly, with one another (e.g., via one or more buses).

The refresh indication component 525 may be configured as or otherwise support a means for setting, to a first value based at least in part on a memory block being scheduled for a refresh operation, a refresh indication for the memory block. The refresh operation component 530 may be configured as or otherwise support a means for initiating the refresh operation for the memory block based at least in part on setting the refresh indication to the first value. In some examples, the refresh indication component 525 may be configured as or otherwise support a means for monitoring, during execution of the refresh operation, a value of the refresh indication, where the value of the refresh indication indicates whether the memory block is valid for the refresh operation.

In some examples, the refresh operation component 530 may be configured as or otherwise support a means for completing the refresh operation based at least in part on refreshing each page of a plurality of pages of the memory block and further based at least in part on the refresh indication being set to the first value, where the first value indicates that the memory block is valid.

In some examples, the refresh operation component 530 may be configured as or otherwise support a means for exiting the refresh operation based at least in part on the refresh indication being set to a second value that indicates that the memory block is invalid.

In some examples, the scheduling component 540 may be configured as or otherwise support a means for scheduling the memory block for one or more access operations different than the refresh operation based at least in part on the refresh indication being set to the second value and exiting the refresh operation.

In some examples, to support executing the refresh operation, the refresh operation component 530 may be configured as or otherwise support a means for performing one or more iterations of the refresh operation, each iteration of the one or more iterations associated with a respective set of page lines of the memory block. In some examples, to support executing the refresh operation, the refresh indication component 525 may be configured as or otherwise support a means for checking the value of the refresh indication after each iteration of the one or more iterations of the refresh operation.

In some examples, to support performing each iteration of the one or more iterations, the read component 545 may be configured as or otherwise support a means for reading the respective set of page lines from the memory block for refresh. In some examples, to support performing each iteration of the one or more iterations, the write component 550 may be configured as or otherwise support a means for writing refreshed data to the respective set of page lines in the memory block.

In some examples, the data component 535 may be configured as or otherwise support a means for moving, by a host system during the execution of the refresh operation, data from the memory block to a destination memory block. In some examples, the refresh indication component 525 may be configured as or otherwise support a means for setting the refresh indication to a second value that indicates the memory block is invalid based at least in part on moving the data. In some examples, the refresh operation component 530 may be configured as or otherwise support a means for exiting the refresh operation based at least in part on the refresh indication being set to the second value.

In some examples, the data component 535 may be configured as or otherwise support a means for writing, by a host system during the execution of the refresh operation, second data to the memory block, where the second data overwrites first data stored in the memory block. In some examples, the refresh indication component 525 may be configured as or otherwise support a means for setting the refresh indication to a second value that indicates the memory block is invalid based at least in part on writing the second data to the memory block during the execution of the refresh operation. In some examples, the refresh operation component 530 may be configured as or otherwise support a means for exiting the refresh operation based at least in part on the refresh indication being set to the second value.

In some examples, the data component 535 may be configured as or otherwise support a means for determining that a valid page count associated with a quantity of pages of the memory block that include invalid data satisfies a threshold value. In some examples, the refresh indication component 525 may be configured as or otherwise support a means for setting the refresh indication to a second value that indicates that the memory block is invalid based at least in part on the valid page count satisfying the threshold value. In some examples, the refresh operation component 530 may be configured as or otherwise support a means for exiting the refresh operation based at least in part on the refresh indication being set to the second value.

In some examples, the memory block is a virtual memory block.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

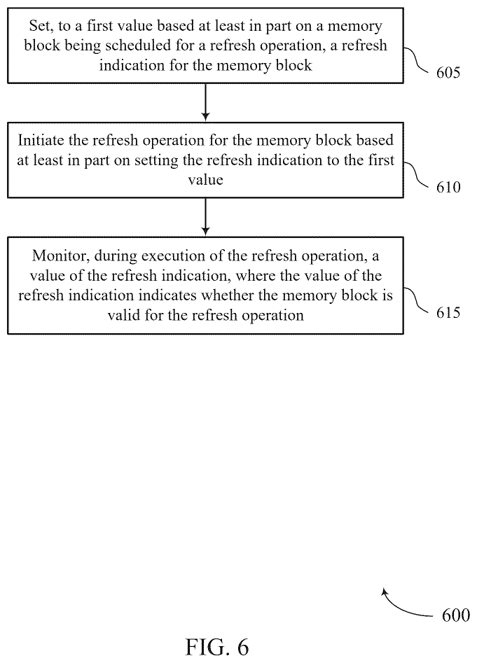

FIG. 6 shows a flowchart illustrating a process 600 that supports indication for exiting refresh of an invalid memory block in accordance with examples as disclosed herein. The operations of process 600 may be implemented by a memory system or its components as described herein. For example, the operations of process 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the process may include setting, to a first value based at least in part on a memory block being scheduled for a refresh operation, a refresh indication for the memory block. In some examples, aspects of the operations of 605 may be performed by a refresh indication component 525 as described with reference to FIG. 5.

At 610, the process may include initiating the refresh operation for the memory block based at least in part on setting the refresh indication to the first value. In some examples, aspects of the operations of 610 may be performed by a refresh operation component 530 as described with reference to FIG. 5.

At 615, the process may include monitoring, during execution of the refresh operation, a value of the refresh indication, where the value of the refresh indication indicates whether the memory block is valid for the refresh operation. In some examples, aspects of the operations of 615 may be performed by a refresh indication component 525 as described with reference to FIG. 5.

In some examples, an apparatus as described herein may perform a process or processes, such as the process 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for setting, to a first value based at least in part on a memory block being scheduled for a refresh operation, a refresh indication for the memory block; initiating the refresh operation for the memory block based at least in part on setting the refresh indication to the first value; and monitoring, during execution of the refresh operation, a value of the refresh indication, where the value of the refresh indication indicates whether the memory block is valid for the refresh operation.

Aspect 2: The method, apparatus, or non-transitory computer-readable medium of aspect 1, further including operations, features, circuitry, logic, means, or instructions, or any combination thereof for completing the refresh operation based at least in part on refreshing each page of a plurality of pages of the memory block and further based at least in part on the refresh indication being set to the first value, where the first value indicates that the memory block is valid.

Aspect 3: The method, apparatus, or non-transitory computer-readable medium of any of aspects 1 through 2, further including operations, features, circuitry, logic, means, or instructions, or any combination thereof for exiting the refresh operation based at least in part on the refresh indication being set to a second value that indicates that the memory block is invalid.

Aspect 4: The method, apparatus, or non-transitory computer-readable medium of aspect 3, further including operations, features, circuitry, logic, means, or instructions, or any combination thereof for scheduling the memory block for one or more access operations different than the refresh operation based at least in part on the refresh indication being set to the second value and exiting the refresh operation.

Aspect 5: The method, apparatus, or non-transitory computer-readable medium of any of aspects 1 through 4, where executing the refresh operation includes operations, features, circuitry, logic, means, or instructions, or any combination thereof for performing one or more iterations of the refresh operation, each iteration of the one or more iterations associated with a respective set of page lines of the memory block and checking the value of the refresh indication after each iteration of the one or more iterations of the refresh operation.

Aspect 6: The method, apparatus, or non-transitory computer-readable medium of aspect 5, where performing each iteration of the one or more iterations includes operations, features, circuitry, logic, means, or instructions, or any combination thereof for reading the respective set of page lines from the memory block for refresh and writing refreshed data to the respective set of page lines in the memory block.

Aspect 7: The method, apparatus, or non-transitory computer-readable medium of any of aspects 1 through 6, further including operations, features, circuitry, logic, means, or instructions, or any combination thereof for moving, by a host system during the execution of the refresh operation, data from the memory block to a destination memory block; setting the refresh indication to a second value that indicates the memory block is invalid based at least in part on moving the data; and exiting the refresh operation based at least in part on the refresh indication being set to the second value.

Aspect 8: The method, apparatus, or non-transitory computer-readable medium of any of aspects 1 through 7, further including operations, features, circuitry, logic, means, or instructions, or any combination thereof for writing, by a host system during the execution of the refresh operation, second data to the memory block, where the second data overwrites first data stored in the memory block; setting the refresh indication to a second value that indicates the memory block is invalid based at least in part on writing the second data to the memory block during the execution of the refresh operation; and exiting the refresh operation based at least in part on the refresh indication being set to the second value.

Aspect 9: The method, apparatus, or non-transitory computer-readable medium of any of aspects 1 through 8, further including operations, features, circuitry, logic, means, or instructions, or any combination thereof for determining that a valid page count associated with a quantity of pages of the memory block that include invalid data satisfies a threshold value; setting the refresh indication to a second value that indicates that the memory block is invalid based at least in part on the valid page count satisfying the threshold value; and exiting the refresh operation based at least in part on the refresh indication being set to the second value.

Aspect 10: The method, apparatus, or non-transitory computer-readable medium of any of aspects 1 through 9, where the memory block is a virtual memory block.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
set, to a first value based at least in part on a memory block being scheduled for a refresh operation, a refresh indication for the memory block;
initiate the refresh operation for the memory block based at least in part on setting the refresh indication to the first value; and
monitor, during execution of the refresh operation, a value of the refresh indication, wherein the value of the refresh indication indicates whether the memory block is valid for the refresh operation.

2. The memory system of claim 1, wherein the processing circuitry is further configured to cause the memory system to:
complete the refresh operation based at least in part on refreshing each page of a plurality of pages of the memory block and further based at least in part on the refresh indication being set to the first value, wherein the first value indicates that the memory block is valid.

3. The memory system of claim 1, wherein the processing circuitry is further configured to cause the memory system to:
exit the refresh operation based at least in part on the refresh indication being set to a second value that indicates that the memory block is invalid.

4. The memory system of claim 3, wherein the processing circuitry is further configured to cause the memory system to:
schedule the memory block for one or more access operations different than the refresh operation based at least in part on the refresh indication being set to the second value and exiting the refresh operation.

5. The memory system of claim 1, wherein executing the refresh operation comprises the processing circuitry configured to cause the memory system to:
perform one or more iterations of the refresh operation, each iteration of the one or more iterations associated with a respective set of page lines of the memory block; and
check the value of the refresh indication after each iteration of the one or more iterations of the refresh operation.

6. The memory system of claim 5, wherein performing each iteration of the one or more iterations comprises the processing circuitry configured to cause the memory system to:
read the respective set of page lines from the memory block for refresh; and
write refreshed data to the respective set of page lines in the memory block.

7. The memory system of claim 1, wherein the processing circuitry is further configured to cause the memory system to:
move, during the execution of the refresh operation, data from the memory block to a destination memory block;
set the refresh indication to a second value that indicates the memory block is invalid based at least in part on moving the data; and
exit the refresh operation based at least in part on the refresh indication being set to the second value.

8. The memory system of claim 1, wherein the processing circuitry is further configured to cause the memory system to:
write, during the execution of the refresh operation, second data to the memory block, wherein the second data overwrites first data stored in the memory block;
set the refresh indication to a second value that indicates the memory block is invalid based at least in part on writing the second data to the memory block during the execution of the refresh operation; and
exit the refresh operation based at least in part on the refresh indication being set to the second value.

9. The memory system of claim 1, wherein the processing circuitry is further configured to cause the memory system to:
determine that a valid page count associated with a quantity of pages of the memory block that include invalid data satisfies a threshold value;
set the refresh indication to a second value that indicates that the memory block is invalid based at least in part on the valid page count satisfying the threshold value; and
exit the refresh operation based at least in part on the refresh indication being set to the second value.

10. The memory system of claim 1, wherein the memory block is a virtual memory block.

11. A non-transitory computer-readable medium storing code comprising instructions which, when executed by one or more processors of a memory system, cause the memory system to:
set, to a first value based at least in part on a memory block being scheduled for a refresh operation, a refresh indication for the memory block;
initiate the refresh operation for the memory block based at least in part on setting the refresh indication to the first value; and
monitor, during execution of the refresh operation, a value of the refresh indication, wherein the value of the refresh indication indicates whether the memory block is valid for the refresh operation.

12. The non-transitory computer-readable medium of claim 11, wherein the instructions, when executed by the one or more processors of the memory system, further cause the memory system to:
complete the refresh operation based at least in part on refreshing each page of a plurality of pages of the memory block and further based at least in part on the refresh indication being set to the first value, wherein the first value indicates that the memory block is valid.

13. The non-transitory computer-readable medium of claim 11, wherein the instructions, when executed by the one or more processors of the memory system, further cause the memory system to:
exit the refresh operation based at least in part on the refresh indication being set to a second value that indicates that the memory block is invalid.

14. The non-transitory computer-readable medium of claim 13, wherein the instructions, when executed by the one or more processors of the memory system, further cause the memory system to:
schedule the memory block for one or more access operations different than the refresh operation based at least in part on the refresh indication being set to the second value and exiting the refresh operation.

15. The non-transitory computer-readable medium of claim 11, wherein the instructions to execute the refresh operation, when executed by the one or more processors of the memory system, further cause the memory system to:
perform one or more iterations of the refresh operation, each iteration of the one or more iterations associated with a respective set of page lines of the memory block; and
check the value of the refresh indication after each iteration of the one or more iterations of the refresh operation.

16. The non-transitory computer-readable medium of claim 15, wherein the instructions to perform each iteration of the one or more iterations, when executed by the one or more processors of the memory system, further cause the memory system to:
read the respective set of page lines from the memory block for refresh; and
write refreshed data to the respective set of page lines in the memory block.

17. The non-transitory computer-readable medium of claim 11, wherein the instructions, when executed by the one or more processors of the memory system, further cause the memory system to:
move, during the execution of the refresh operation, data from the memory block to a destination memory block;
set the refresh indication to a second value that indicates the memory block is invalid based at least in part on moving the data; and
exit the refresh operation based at least in part on the refresh indication being set to the second value.

18. The non-transitory computer-readable medium of claim 11, wherein the instructions, when executed by the one or more processors of the memory system, further cause the memory system to:
write, during the execution of the refresh operation, second data to the memory block, wherein the second data overwrites first data stored in the memory block;
set the refresh indication to a second value that indicates the memory block is invalid based at least in part on writing the second data to the memory block during the execution of the refresh operation; and
exit the refresh operation based at least in part on the refresh indication being set to the second value.

19. A method by a memory system, comprising:
setting, to a first value based at least in part on a memory block being scheduled for a refresh operation, a refresh indication for the memory block;
initiating the refresh operation for the memory block based at least in part on setting the refresh indication to the first value; and
monitoring, during execution of the refresh operation, a value of the refresh indication, wherein the value of the refresh indication indicates whether the memory block is valid for the refresh operation.

20. The method of claim 19, further comprising:
completing the refresh operation based at least in part on refreshing each page of a plurality of pages of the memory block and further based at least in part on the refresh indication being set to the first value, wherein the first value indicates that the memory block is valid.
